(19) United States
(12) Patent Application Publication
(10) Pub. No.: US 2015/0041645 A1
(43) Pub. Date: Feb. 12, 2015

(54) IMAGE ACQUISITION APPARATUS, IMAGE ACQUISITION METHOD AND DEFECT INSPECTION APPARATUS

(71) Applicants: KABUSHIKI KAISHA TOSHIBA, Tokyo (JP); EBARA CORPORATION, Tokyo (JP)

(72) Inventors: Susumu IIDA, Yoshikawa Saitama (JP); Ryoichi HIRANO, Tokyo (JP); Hidehiro WATANABE, Tokyo (JP); Masahiro HATAKEYAMA, Tokyo (JP)

(21) Appl. No.: 14/453,099

(22) Filed: Aug. 6, 2014

(30) Foreign Application Priority Data
Aug. 7, 2013 (JP) 2013-164427

(51) Int. Cl. H01J 37/24; H01J 37/26

(52) U.S. Cl. CPC H01J 37/243; H01J 37/26
USPC 250/307; 250/310

(57) ABSTRACT

According to one embodiment, an image acquisition apparatus includes an electron beam source configured to generate an electron beam to be radiated onto an object to be measured, an image detecting unit configured to detect an electronic image of the object based on the electron beam radiated from the electron beam source onto the object, and a voltage modulating unit configured to modulate at least one of a voltage to be applied to the electron beam source and a voltage to be applied to the object.

### CROSS-REFERENCE TO RELATED APPLICATIONS

This application is based upon and claims the benefit of priority from Japanese Patent Application No. 2013-164427, filed Aug. 7, 2013, the entire contents of which are incorporated herein by reference.

### FIELD

Embodiments described herein relate generally to an image acquisition apparatus, an image acquisition method and a defect inspection apparatus.

### BACKGROUND

As semiconductor devices are made smaller, a defect inspection of semiconductor wafers or photomasks is required to detect a smaller defect. It is therefore important that a defect inspection is performed with a high precision and at a high speed.

In the case of making a defect inspection, in general, an electron beam is radiated onto an object (sample) to be measured such as a semiconductor wafer or a photomask, and secondary electrons or mirror electrons from the object are detected, to thereby generate an electronic image (electron-microscopic image, electrooptical image).

The characteristic (feature) of the electronic image varies in accordance with the kind thereof (for example, in accordance with whether the electronic image is a secondary electron image or a mirror electron image). Therefore, if a plurality of kinds of electronic images are acquired from the same object to be measured, it is possible to acquire a proper image which usefully reflects features of the plurality of electronic images, and make a defect inspection with a high precision.

However, in order to acquire a plurality of electronic images, it is necessary to perform measurement a number of times. As a result, it takes longer time to acquire the plurality of electronic images; that is, the electronic images cannot be efficiently acquired.

Therefore, it is hoped to provide an image acquisition apparatus or the like which enables a proper image to be efficiently acquired.

### BRIEF DESCRIPTION OF THE DRAWINGS

FIG. 1 is a view showing a structure of an image acquisition apparatus according to a first embodiment;

FIG. 2 is a view schematically showing an example of an object to be measured, with respect to a first embodiment;

FIG. 3 is a view schematically showing an equipotential surface of a surface of the object with respect to the first embodiment;

FIG. 4 is a view schematically showing an electronic image in the case where the energy of incident electrons is 1 eV, with respect to the first embodiment;

FIG. 5 is a view schematically showing an electronic image in the case where the energy of incident electrons is 500 eV, with respect to the first embodiment;

FIG. 6 is a view schematically showing an electronic image in the case where the energy of incident electrons is 2000 eV, with respect to the first embodiment;

FIG. 7 is a timing chart of the energy of incident electrons with respect to the first embodiment;

FIG. 8 is a view showing an example of a composite electronic image obtained by an image composition unit;

FIG. 9 is a flowchart showing an image acquisition method according to the first embodiment;

FIG. 10 is a block view showing a structure of a defect inspection apparatus with respect to the first embodiment;

FIG. 11 is a timing chart of the energy of incident electrons with respect to a second embodiment;

FIG. 12 is a timing chart of the energy of incident electrons with respect to a third embodiment;

FIG. 13 is a view showing thin-film defects with respect to a fourth embodiment;

FIG. 14 shows a principle of the fourth embodiment;

FIG. 15 is a timing chart of an incident electron energy with respect to the fourth embodiment;

FIG. 16 is a view showing a structure of an image acquisition apparatus according to a fifth embodiment;

FIG. 17 is a timing chart showing switching of a power supply voltage with respect to the fifth embodiment;

FIG. 18 is a view showing a structure of an image acquisition apparatus according to a sixth embodiment; and

FIG. 19 is a view showing a structure of a modification of the image acquisition apparatus according to the sixth embodiment.

### DETAILED DESCRIPTION

In general, according to one embodiment, an image acquisition apparatus includes: an electron beam source configured to generate an electron beam to be radiated onto an object to be measured; an image detecting unit configured to detect an electronic image of the object based on the electron beam radiated from the electron beam source onto the object; and a voltage modulating unit configured to modulate at least one of a voltage to be applied to the electron beam source and a voltage to be applied to the object.

Embodiments will be explained with reference to the accompanying drawings.

### First Embodiment

FIG. 1 is a view showing a structure of an image acquisition apparatus 10 according to a first embodiment. The image acquisition apparatus 10 according to the first embodiment can basically be applied to an electron microscope device, and can also be applied to a defect inspection device (a defect inspection device for a semiconductor wafer or a photomask).

An object 11 to be measured (a sample to be measured) such as a semiconductor wafer or a photomask is provided on a stage 12. Furthermore, an electron beam source 15 comprising an electron gun 13 and an anode 14 is located on a line extending obliquely upwards from the stage 12. The electron beam source 15 produces an electron beam to be radiated on the object 11. It is possible to radiate the electron beam on desired part of the object 11 by moving the stage 12. The electron beam produced by the electron beam source 15 is radiated on the object 11 through an F electrooptical system 17.

Also, an image detecting unit 18 is provided above the stage 12. The image detecting unit. 18 detects an electronic image (electron-microscopic image or electrooptical image) to be measured, based on the electron beam radiated from the electron beam source 15 on the object 11. To be more specific, when the electron beam is radiated on the object 11, secondary electrons or mirror electrons generate, and an electronic image based on the secondary electrons or mirror electrons is detected by the image detecting unit 18. The secondary electrons or mirror electrons from the object 11 are incident on the image detecting unit 18′ through the E×B electrooptical system 17.

To the electron beam source 15, a voltage modulation unit 20 is connected, which modulates a voltage to be applied to the electron beam source 15. It should be noted that in the first embodiment, the voltage modulation unit 20 modulates the voltage to be applied to the electron beam source 15; however, it may be formed to modulate a voltage to be applied to the object 11. In general, a voltage modulation unit modulates at least one of a voltage to be applied to the electron beam source 15 and a voltage to be applied to the object 11.

The voltage modulation unit 20 can apply a desired voltage between the electron gun 13 and the anode 14. Thereby, desired energy can be given to electrons which are incident on the object 11. For example, the voltage modulation unit 20 enables the energy of the incident electrons to be set to a desired value which falls within the range of 1 eV to 2000 eV.

If the energy of electrons to be made incident on the object 11 is approximately 1 eV, the electrons do not reach the object due to electrons with which the object 11 is charged, and mirror electrons are detected at the image detecting unit 18. If the energy of electrons to be made incident on the object 11 is approximately 2000 eV, secondary electrons generate from the object 11, and the secondary electrons are detected at the image detecting unit 18. That is, it is possible to detect a plurality of kinds of electronic images at the image detecting unit 18 by modulating with the voltage modulation unit, at least one of the voltage to be applied to the electron beam source 15 and that to be applied to the object 11,

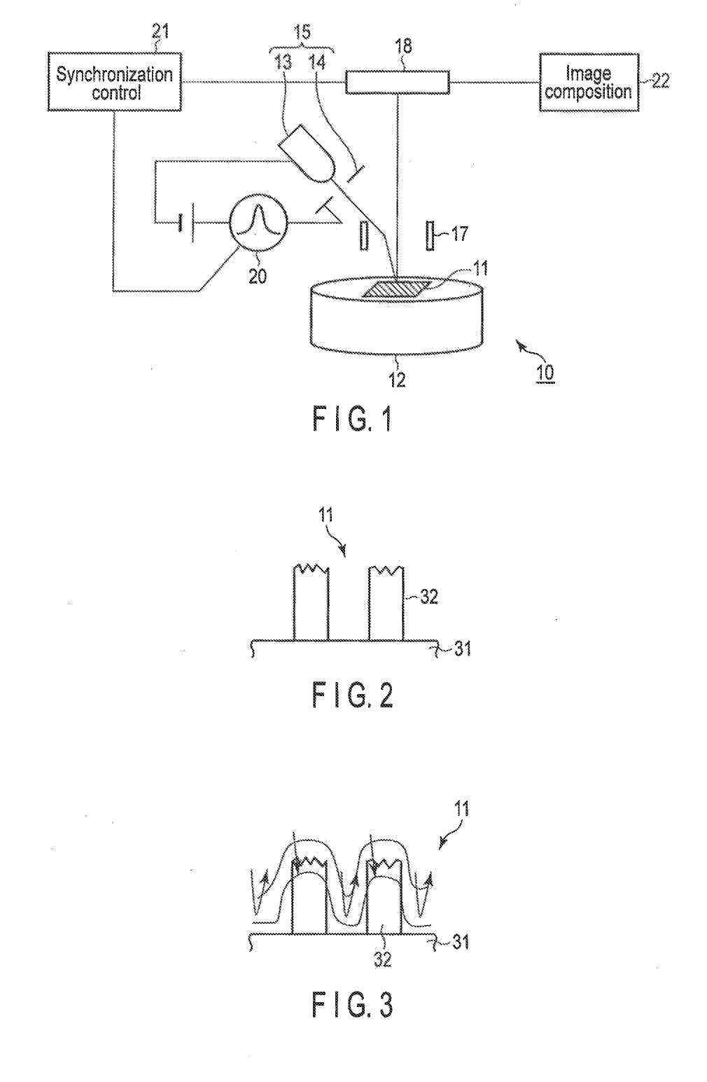

FIG. 2 is a view schematically showing an example of an object 11 to be measured. In the first embodiment, as the object 11, a reflection type photomask for extreme ultraviolet (EUV) exposure is applied. The reflection type photomask includes a metallic layer (e.g., Ru layer) 31 and an absorption layer (e.g., a TaBO layer or a TaNO layer) 32 provided on the metallic layer 31. The metallic layer 31 is formed of an electric conductor which reflects EUV light, and the absorption layer 32 is formed of an insulator (dielectric) which absorbs EUV light. Furthermore, a surface of a projecting portion formed of the absorption layer 32 is rough in such a manner to have minute irregularities.

FIG. 3 is a view schematically showing an equipotential surface of a surface of the object (the reflection type photomask) as shown in FIG. 2. At a recess portion of the object 11, the metallic layer 31 is exposed; however, the absorption layer 32, which corresponds to a projecting portion of the object 11, is formed of an insulator. Thus, although at the recess portion, the equipotential surface is located on an outer periphery of the object 11, at the projecting portion, the equipotential surface is located in the absorption layer (insulating layer) 32. Thus, if the energy of incident electrons is set to 1 eV, at the recess portion, incident electrons do not reach the metallic layer 31, and reflect as mirror electrons. On the other hand, at the projecting portion, incident electrons collide against the absorption layer 32. Therefore, at the projecting portion, mirror electrons do not generate. Furthermore, since the energy of incident electrons is very low, at the projecting portion, few secondary electrons generate. As a result, the image detecting unit 18 detects an image based on the mirror electrons from the recess portion.

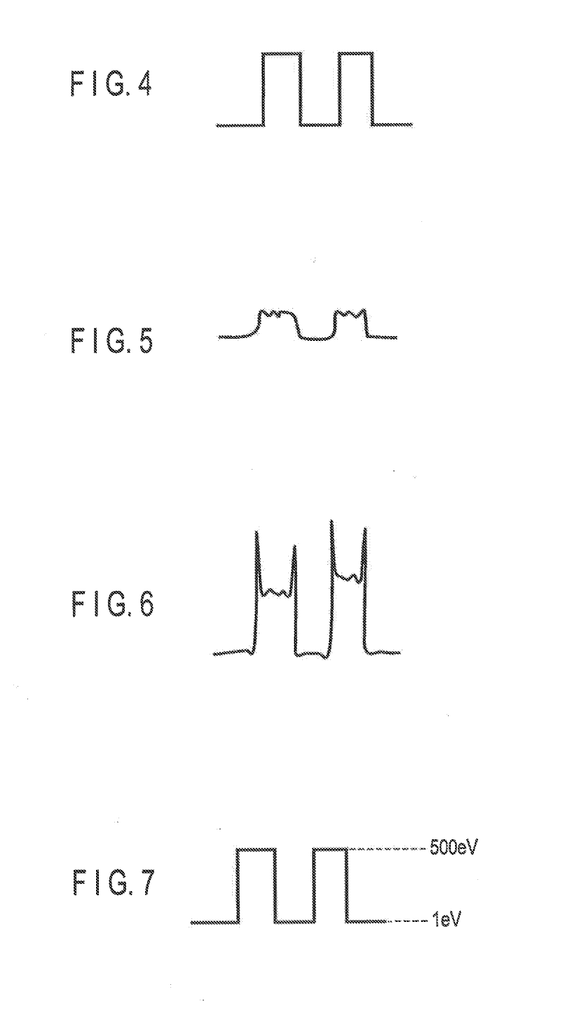

FIG. 4 is a view schematically showing an electronic image detected by the mage detector 18 in the case where the energy of incident electrons is set to 1 eV as described above. As shown in FIG. 4, the image has a high contrast between the recess portion where the metallic layer 31 is exposed and the projecting portion formed of the absorption layer (insulating layer) 32. However, since few electrons generate at the projecting portion, a rough surface having minute irregularities at the projecting portion is hardly detected.

FIG. 5 is a view schematically showing an electronic image detected by the image detecting unit 18 in the case where the energy of incident electrons is 500 eV. In this case, secondary electrons are emitted from the object 11. As a result, although the contrast between the recess portion and the projecting portion is low, a rough surface having minute irregularities at the projecting portion is detected.

FIG. 6 is a view schematically showing an electronic image detected by the image detecting unit 18 in the case where the energy of incident electrons is set to 2000 eV. In this case, a large number of secondary electrons generate at a boundary (edge) between the recess portion and the projecting portion, thus acquiring an image whose edge is highlighted.

As described above, it is possible to acquire various images which vary in accordance with the energy of incident electrons, by changing the energy thereof. Those various images have different features. Therefore, if the images are used in combination, a proper image to be measured can be acquired. However, if measurement is carried out a number of times, with the energy of incident electrons set to different values, it takes a longer time to acquire an image; that is, the image cannot be efficiently obtained. For example, if measurement is carried out two times to acquire two kinds of images, the time required to acquire those images is at least double that in the case where measurement is carried out only once.

In the first embodiment, the energy of incident electrons is changed in a time-division manner, and a plurality of kinds of images are acquired by the same measurement processing.

FIG. 7 is a timing chart showing the energy of incident electrons, which is changed in a time-division manner. When the voltage modulation unit 20 performs voltage modulation, the energy of incident electrons is changed in such a manner as shown in FIG. 7. In an example shown in FIG. 7, switching between 1 eV and 500 eV is effected with a duty ratio of 50%.

Re-referring to FIG. 1, a synchronization control unit 21 is provided to acquire a plurality of kinds of images with the same measurement processing. The synchronization control unit 21 causes voltage modulation timing by the voltage modulation unit 20 and image detection timing by the image detecting unit 18 to be synchronized with each other. In such a manner, since the voltage modulation and the image detection are synchronized with each other by the synchronization control unit 21, a plurality of kinds of electronic images can be individually acquired in association with a plurality of energies of incident electrons, respectively.

To the image detecting unit 18, the image composition unit 22 is connected. The image composition unit 22 combines the plurality of kinds of electronic images obtained in the above manner.

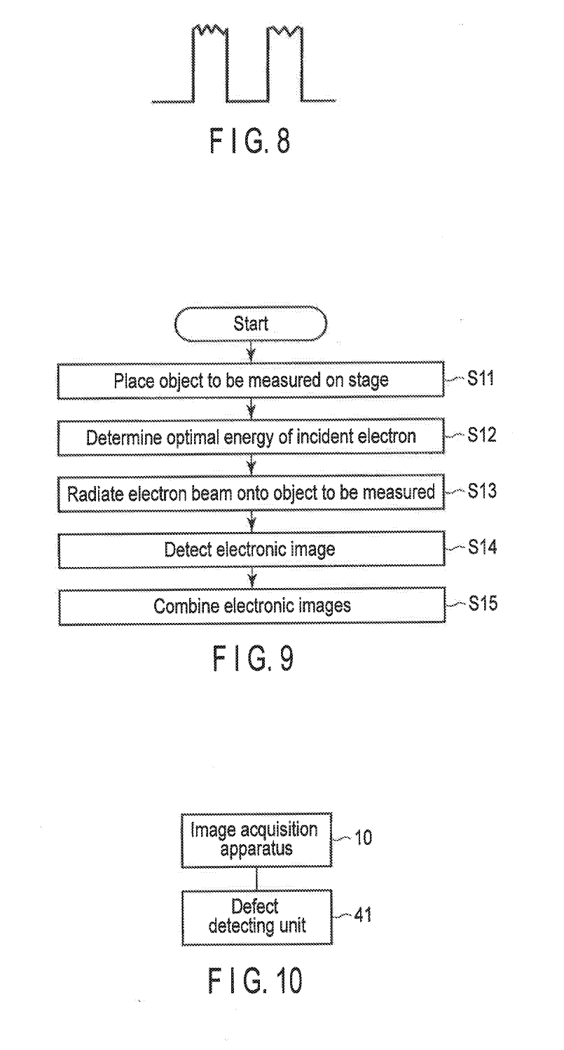

FIG. 8 shows an example of a composite electronic image acquired by the image composition unit 22. The example of the composite electronic image as shown in FIG. 8 is a composite image acquired by combining such an image as shown in FIG. 4 (an image acquired in the case where the energy of incident electrons is 1 eV) and such an image as shown in FIG. 5 (an image acquired in the case where the energy of incident electrons is 500 eV).

It should be noted that in the case of acquiring a plurality of electronic images associated with a plurality of energies of incident electrons, respectively, it may be set that optimal energies of incident electrons are determined in advance with pre-scanning. To be more specific, a sine wave is generated by the voltage modulation unit 20, and the energy of incident electrons is changed in accordance with the sine wave. As a result, it is possible to obtain a plurality of images associated with the energies of incident electrons, respectively. Based on a result obtained in the above manner, optimal energies of incident electrons are determined. For example, in the case of acquiring both a mirror electron image and a secondary electron image, an optimal energy of incident electrons for the mirror electron image and an optimal energy of incident, electrons for the secondary electron image are determined. Then, such a time-division scanning as shown in FIG. 7 is performed with the optimal energies of incident electrons which are determined in the above manner.

Next, an image acquisition method according to the first embodiment will be explained with reference to the flowchart shown in FIG. 9.

First, the object 11 to be measured (which corresponds to the reflection type photomask for EUV exposure light in the first embodiment) is placed on the stage 12 (S11).

Next, a sine wave is generated by the voltage modulation unit 20, and pre-scanning is performed. Furthermore, based on the result of the pre-scanning, optimal energies of incident electrons are determined for images to be acquired, respectively (S12). For example, with respect to a mirror electron image, the energy of incident electrons is determined as 1 eV, and with respect to a secondary electron image, the energy of incident electrons is determined as 500 eV.

Then, the voltage modulation unit 20 is controlled to cause the electron beam source 15 to generate an electron beam, and the generated electron beam is radiated on the object 11 (S13). At this time, it modulates a voltage to be applied to the electron beam source 15. That is, the voltage modulation unit 20 is controlled so as to obtain the optimal energies of incident electrons which are determined in the step S12, and such time-division scanning as shown in, e.g., FIG. 7 is performed. It should be noted that although in the first embodiment, the voltage modulation unit 20 modulates a voltage to be applied to the electron beam source 15, it may modulate a voltage to be applied to the object 11. In general, a voltage modulation unit modulates at least one of a voltage to be applied to the electron beam source 15 and that to be applied to the object 11.

Next, an electronic image of the object 11 based on the electron beams radiated on the object 11 is detected by the image detecting unit 18 (S14). At this time, the synchronization control unit 21 causes voltage modulation by the voltage modulation unit 20 and image detection by the image detecting unit 18 to be synchronized with each other. Thereby, it is possible to acquire individually a plurality of kinds of electronic images respectively associated with the energies of incident electrons. In the first embodiment, such a mirror electron image as shown in FIG. 4 and such a secondary electron image as shown in FIG. 5 are acquired.

Then, electronic images acquired in the step S14 are combined by the image composition unit 22 (S15). As a result, such a composite image as shown in FIG. 8 is acquired.

In such a manner, in the first embodiment, as the result of the voltage modulation by the voltage modulation unit, an electron beam is radiated on the object to be measured, with the energy of incident electrons which varies temporally. Thus, the plurality of kinds of electronic images can be acquired by the same measurement processing. Accordingly, the kinds of electronic images can be acquired without increasing the time required to acquire the images. It is therefore possible to efficiently acquire appropriate electronic images having different features.

A defect inspection apparatus using the above image acquisition apparatus and a defect inspection method using the above image acquisition method will be explained.

FIG. 10 is a block diagram showing a structure of the defect inspection apparatus. The defect inspection apparatus as shown in FIG. 10 comprises a defect detection unit 41 and the image acquisition apparatus 10 as shown in FIG. 1.

The defect detection unit 41 detects a defect in the object to be measured, based on an image acquired by the image acquisition apparatus 10. To be more specific, the defect detection unit 41 performs defect detection based on a composite image acquired by composition processing by the image composition unit 22 as shown in FIG. 1. In the first embodiment, defect detection is performed based on a composite image acquired by combining a secondary electron image and a mirror electron image.

The secondary electron image is obtained as a distinct image having a great S/N ratio. In this regard, the secondary electron image has an advantage. However, there is a case where an insulator is formed on a surface of a semiconductor wafer or a photomask which is the object to be measured, and the surface of such an object to be measured is charged up. Thus, there is also a case where the secondary electron image is blurred or distorted. On the other hand, with respect to the mirror electron image, mirror electrons are reflected at an equipotential surface close to the surface of the object, and thus do not greatly act on the object. Therefore, the influence of charging-up upon the mirror electron image is small. Furthermore, since the mirror electron image is influenced by an equipotential surface distorted due to a defect, a defect signal is highlighted. In this regard, the mirror electron image has an advantage. Therefore, the secondary electron image and the mirror electron image are combined to enable a defect to be detected by utilizing the advantages of the secondary electron image and the mirror electron image.

Furthermore, in the case of performing a measurement for defect detection, there is a case where a pseudo-defect caused by electrical noise or the like is determined by mistake as a defect. For such a pseudo-defect, it is possible to make a proper determination by using a plurality of kinds of images (e.g., a secondary electron image and a mirror electron image). However, in the case where a large number of pseudo-defects are present, if a plurality of kinds of images are acquired by respective measurements, it is not found that the large number of pseudo-defects are present, until the plurality of kinds of images are acquired by the respective measurements. In such a case, it is necessary to change set conditions and re-perform the measurements from the beginning with the changed conditions, thus spending a lot of time. On the other hand, in the above case, if a plurality of kinds of images are acquired by a single measurement as in the first embodiment, it can be determined in an initial stage of the measurement that a large number of pseudo-defects are present. It is therefore possible to set the conditions in the initial stage of the measurement, and re-perform the measurement, thus avoiding consumption of a lot of time.

As described above, in the defect inspection apparatus according to the first embodiment, defection inspection is performed based on a plurality of kinds of electronic images acquired by a single measurement, thereby enabling a proper defect inspection to be efficiently performed.

### Second Embodiment

Next, the second embodiment will be explained. It should be noted that basic matters of the second embodiment are the same as those of the first embodiment, and thus the matters explained with respect to the first embodiment will not be re-explained with respect to the second embodiment.

In the first embodiment, as explained above, the energy of incident electrons is switched at a 50% duty; that is, time periods set for a plurality of energies of incident electrons are equal to each other. On the other hand, in the second embodiment, time periods for a plurality of energies of incident electrons are set different from each other.

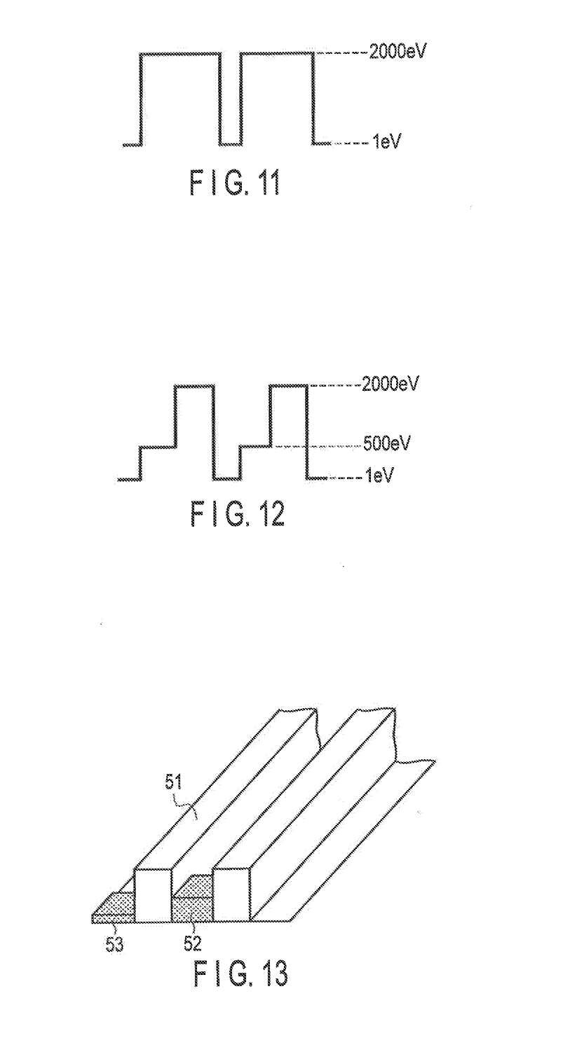

FIG. 11 is a timing chart showing switching between the energies of incident electrons in the second embodiment. In an example shown in FIG. 11, by controlling the voltage modulation unit 20, the percentage of the time period set for the energy (2000 eV) of incident electrons for acquisition of a secondary electron image is 80%, and that for the energy (1 eV) of incident electrons for acquisition of a mirror electron image is 20%.

In general, a mirror electron image is acquired to have a high luminance and a high contrast. On the other hand, a secondary electron image is acquired to enable a pattern to be viewed in detail; however, it has a low luminance than the mirror electron image. Thus, as shown in FIG. 11, a time period required to acquire a secondary electron image is set longer than that to acquire a mirror electron image, as a result of which an appropriate image can be acquired.

As described above, in the second embodiment, a proper defect inspection can be efficiently made by making defect inspection based on a plurality of kinds of electronic images acquired by the same measurement processing as in the first embodiment. Furthermore, in the second embodiment, a more proper image can be acquired and a more proper defect inspection can be efficiently made, by appropriately setting time periods required to acquire a plurality of kinds of electronic images.

### Third Embodiment

The third embodiment will be explained. It should be noted that basic matters of the third embodiment are the same as those of the first embodiment, and thus the matters explained with respect to the first embodiment will not be re-explained with respect to the third embodiment.

As to the third embodiment, the following explanation is given with respect to the case where three kinds of electronic images are acquired using three energies of incident electrons, especially the case where as the object 11, a semiconductor wafer is used

FIG. 12 is a timing chart showing switching between energies of incident electrons in the third embodiment.

On a surface of a semiconductor wafer where a circuit pattern is formed, various materials such as an electric conductor and an insulator are mixedly provided. Thus, the surface of the semiconductor wafer contains regions having different conductivities and permittivities. In view of this point, in the third embodiment, the voltage modulation unit 20 is controlled to acquire three incident electron energies (1 eV, 500 eV and 2000 eV) as shown in FIG. 12. Since the efficiency of generation of secondary electrons varies in accordance with the material to be provided, a plurality of energies (500 eV and 2000 eV) of incident electrons are applied for generation of secondary electrons, thereby enabling a proper image to be acquired in accordance with a provided material. Furthermore, in order to improve the contrast of an image to be acquired as a whole, energy of 1 eV of incident electrons is used for generation of mirror electrons.

As described above, it is possible to acquire an proper image and efficiently make proper defect inspection by increasing the number of energy values of incident electrons, even if regions having different electric conductivities and permitivities are mixedly provided as in the surface of a semiconductor wafer.

### Fourth Embodiment

A fourth embodiment will be explained. It should be noted that basic matters of the fourth embodiment are the same as those of the first embodiment, and thus the matters explained with respect to the first embodiment will not be re-explained with respect to the fourth embodiment.

Not all defects existing on a photomask are transferred onto a wafer; that is, of the defects on the photomask, a defect or defects are not transferred onto the wafer.

FIG. 13 is a view showing defects on the photomask, i.e., a defect to be transferred and a defect not to be transferred. Also, FIG. 13 shows the case where thin-film defects formed of insulators (dielectrics) are present in grooves between periodic line patterns 51. To be more specific, in the case shown in FIG. 13, a thin-film defect 52 having a greater thickness than a given thickness and a thin-film defect 53 hawing a smaller thickness than the given thickness are present in grooves between line patterns 51.

When lithography is applied, the thin-film defect 52 having the greater thickness than the given thickness is transferred, whereas the thin-film defect 53 having the smaller thickness than the given thickness is not transferred. Therefore, the thin-film defect 53 is a pseudo-defect, and it is therefore preferable that the thin-film defect 53 should not be detected as a defect. If it is detected as a defect, the amount of data is increased, thus also increasing the time required for inspection. Therefore, in the fourth embodiment, by properly setting a point at which mirror electrons are returned, it is set that the thin-film defect 52 having the greater thickness is detected as a defect, and the thin-film defect 53 having the smaller thickness is not detected as a defect.

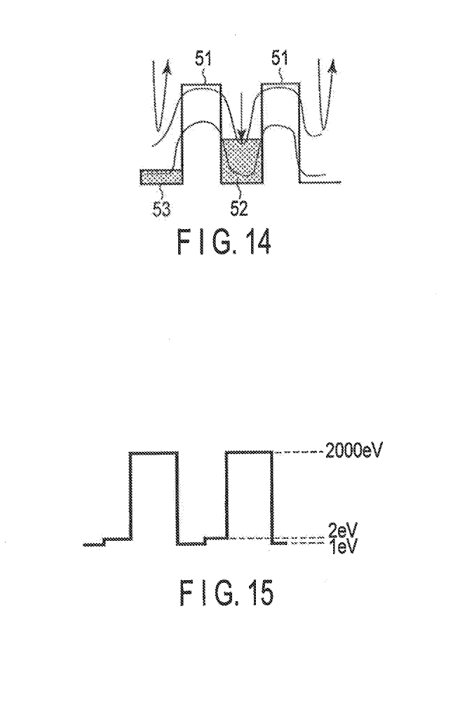

FIG. 14 is a view showing a principle of defect detection in the fourth embodiment. According to the principle, for example, in the case where the energy of incident electrons is 2 eV, at a region where no thin-film defect is present in a groove, mirror electrons are detected, and at a region where the thin-film defect 52 having the greater thickness and the thin-film defect 53 having the smaller thickness are present in the grooves, mirror electrons are not detected. Furthermore, in the case where the energy of incident electrons is 1 eV, at the region where no thin-film defect is present in the groove and where the thin-film defect 53 having the smaller thickness is present, mirror electrons are detected, and at the region where the thin-film defect 52 having the greater thickness is present in the groove, mirror electrons are not detected. In such a case, it is set that the region where although mirror electrons are not detected in the case where the energy of incident electrons is 2 eV, mirror electrons are detected in the case where the energy of incident electrons is 1 eV is considered as a region where the thin-film defect 53 not to be transferred is present, i.e., a region having no defect. Furthermore, the region where mirror electrons are not detected in both the cases where the energy of incident electrons is 2 eV and where it is 1 eV is considered as a region where the thin-film defect 52 having the greater thickness and to be transferred is present, i.e., a region having a defect.

FIG. 15 is a timing chart showing switching between the energies of incident electrons in the fourth embodiment. As shown in FIG. 15, the energy (1 eV, 2 eV, 2000 eV) of incident electrons is switched in a time-division manner. As described above, in the case where the energy of incident electrons is 2000 eV, a secondary electron image is detected. Due to the secondary electron image, an entire image of the photomask can be acquired.

As described above, in the fourth embodiment also, defect inspection is performed based on a plurality of electronic images acquired by the same measurement processing, as in the first embodiment, thereby enabling proper defect inspection to be efficiently performed. Furthermore, in the fourth embodiment, the point at which mirror electrons are returned is appropriately set to enable a defect not to be transferred onto a wafer to be distinguished from a defect to be transferred onto the wafer. It is therefore possible to efficiently perform a properer defect inspection.

It should be noted that by applying the method (principle) described with respect to the fourth embodiment, it is possible to measure the thickness of a thin film formed of an insulator (dielectric) without contacting the thin film. An application of the fourth embodiment will be explained.

As can be seen from the above, when an electron beam is radiated on the thin film formed of an insulator (dielectric), there is a case where mirror electrons are detected and also a case where they are not. This depends on the energy of incident electrons. From another standpoint, in accordance with the thickness of the thin film, there is a case where mirror electrons are detected and also a case where mirror electrons are not. In view of this point, a relationship between the thickness of the thin film and a boundary value (boundary energy) between the energy of incident electrons at which mirror electrons are detected and that of incident electrons at which mirror electrons are not detected is determined in advance. As a result, it is possible to measure the thickness of the thin film without contacting it, from the boundary value. For example, in the case of determining the thickness of a given thin film, detection of mirror electrons is performed while increasing the energy of incident electrons on the thin film from low energy to high energy. In this case, the energy of incident electrons at which it becomes impossible to detect mirror electrons is determined as the above boundary value (boundary energy) of incident electrons. In such a manner, if the relationship between the thickness of the thin film and the boundary energy of incident electrons is determined in advance, the thickness of the thin film can be determined from the determined boundary value.

In such a manner, according to the above application of the fourth embodiment, it is possible to determine the thickness of a thin film formed of an insulator (dielectric) without contacting the thin film by radiating an electron beam on the thin film.

In the first to fourth embodiments, as the method of acquiring an electronic image, a scanning electron microscope type of image acquisition method or a projection electron microscopy type image acquisition method having a radiation system and a detection system (imaging system) may be applied. In the scanning electron microscope type of image acquisition method, an electron beam is focused on the surface of the object to be measured, and the focused electron beam is scanned over the surface of the object, thereby acquiring an electronic image. In the projection electron microscopy type image acquisition method, the radiation system is set such that an electron beam is radiated while two-dimensionally spreading over the surface of the object, and due to the electron beam radiated while two-dimensionally spreading, an electronic image acquired from the inside of the object, the surface thereof or the vicinity of the surface is enlarged by the detection system (imaging system), and is picked up at the image detecting unit, thereby acquiring an electronic image.

### Fifth Embodiment

The fifth embodiment will be explained. It should be noted that basic matters of the fifth embodiment are the same as those of the first embodiment, and thus the matters explained with respect to the first embodiment will not be re-explained with respect to the fifth embodiment.

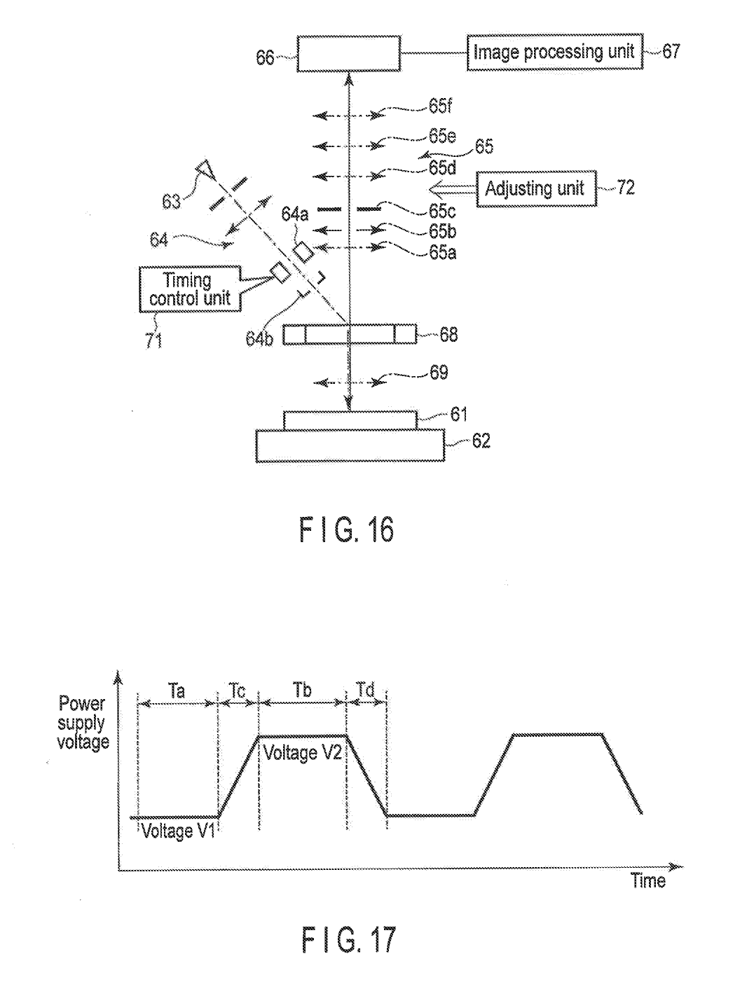

In the fifth embodiment, an electronic image is acquired using a projection electron microscopy type image acquisition apparatus. FIG. 16 is a view schematically showing a structure of the projection electron microscopy type image acquisition apparatus according to the fifth embodiment.

An object (sample) 61 to be measured is placed on a stage 62, and an electron beam is radiated from an electron beam source 63 onto the object 61 through an electron beam radiation system 64. Electrons from the object 61 are incident on an image detecting unit 66 after being subjected to enlargement processing by the electron image projection system 65. Image data on an electronic image detected by the image detecting unit 66 is sent to an image processing unit 67. Then, based on a result of image processing by the image processing unit 67, a defect of a mask blank is detected. The electron beam radiation system 64 comprises a gun lens, an aperture (not shown), an aligner (for beam deflection, not shown), an aligner 64a for high-speed deflection and an aperture 64b for blanking. Through those elements, electrons generated by the electron beam source 63 is incident on a beam separation unit (beam separator) 68. The incident electrons are directed toward the object 61 by the beam separation unit 68. As a result, the electron beam is radiated on the object 61 in a direction perpendicular to a surface of the object 61.

Electrons from the object 61 are incident on the beam separation unit 68 through the lens 69. The beam separation unit 68 has a function of separating the electron beam radiated from the electron beam radiation system 64 and directed toward the object 61 and the electrons directed from the object 61 toward the electron image projection system 65. It should be noted that in order to restrict distortion and aberration of an electron beam enlargedly projected by the electron image projection system 65, a Wien condition (a condition under which an electron beam straightly travels) is applied to the electron beam to be enlargedly projected.

The electron beam passing through the beam separation unit 68 also passes through a relay lens 65a, a stigmator 65b and an NA aperture 65c, and is then enlargedly projected on the image detecting unit 66 by zoom lenses 65d and 65e and an enlargement projection lens 65f. It should be noted that at centers of the relay lens 65a, the zoom lenses 65d and 65e and the enlargement projection lens 65f, there is provided a deflector (not shown) for adjusting the position of the beam to be enlargedly projected.

The image detecting unit 66 comprises a time delay integration charge-coupled device (TDI-CCD) sensor. It will be explained how a continuous image is acquired by the TDI-CCD sensor. For example, if a TDI-CCD sensor having 2000 pixels in a longitudinal direction and 500 pixels in a transverse direction is used, an acquired continuous image has a 2000-pixel width, and the number of integrating steps of continuous movement is 500. If a line frequency is 200 kHz, the time required for movement of one step in an integrating direction is 5 μsec. Therefore, integrating time for 500 steps is 2.5 msec. If a single frame image has 2000×2000 pixels, it takes 10 msec to acquire a single frame image. In the TDI-COD sensor, images (signals) at the same position in the object to be measured are integrated and output, as a result of which it is possible to acquire an image having a high sensitivity and a high resolution at a high speed.

FIG. 17 is a timing chart in the case where a power supply voltage is switched between voltage V1 and voltage V2. In an example shown in FIG. 17, Tc is a transition time period from voltage V1 (application time Ta) to voltage V2 (application time Tb), and Td is a transition time period from voltage V2 to voltage V1. In this case, it is preferable that the transition time period Tc and the transition time period Td be both equal to or less than ⅓ of time Ta, and also equal to or less than ⅓ of time Tb.

As described above, when the voltage is switched, a transition time period is present. In the transition time period, since the voltage changes, imaging conditions of the electron beam radiation system and the electron image projection system greatly badly change. Thus, the size of the electron beam of the electron beam radiation system and the focus and magnification of the electron image projection system are greatly changed from their correct ones. Therefore, if an image signal is detected by the image detecting unit during the transition time period (Tc, Td), a blurred image is detected.

In order to solve the above problem, in the fifth embodiment, in the transition time period of the voltage, i.e., when the voltage is switched, blanking of the electron beam of the electron beam radiation system is performed. Specifically, the radiated beam is deflected to an end portion of an aperture 64b for blanking by an aligner 64a for high-speed deflection in the electron beam radiation system 64 as shown in FIG. 16. To be more specific, a timing control unit 71 is provided, and controls a deflection timing of the aligner 64a for high-speed deflection in accordance with a voltage switching timing of a power supply (corresponding to the voltage modulation unit 20 as shown in FIG. 1). Thereby, the beam is prevented from being radiated onto the object 61. The device according to the fifth embodiment comprises a radiation controlling unit which exerts a control of preventing the electron beam emitted from the electron beam source from being radiated onto the object during the transition time period in which the voltage is switched by the voltage modulation unit. In the fifth embodiment, the radiation, controlling unit corresponds to the timing control unit 71, the aligner 64a for high-speed deflection and the aperture 64b for blanking.

In such a manner, in the fifth embodiment, a clear image can be acquired by performing blanking of the electron beam (radiated beam) in accordance with the switching timing of the power supply voltage (the transition time period of the power supply voltage).

It is preferable that a blanking time period be longer than the transition time period (the period Tc, Td as shown in FIG. 17) by approximately 5 to 20%. Furthermore, if a voltage rising time period (the time period Tc in FIG. 17) in which the voltage is risen is different from a voltage drop time period (the time period Td in FIG. 17) in which the voltage is dropped, it is preferable that optimal blanking time periods be set in the voltage rising time period and the voltage drop time period, respectively.

In the case of acquiring a continuous image with the TDI camera, there can be a case where voltage modulation is performed at a higher speed than a line frequency or a case where voltage modulation is performed within a single frame period.

In the case where voltage modulation is performed at a higher speed than the line frequency, in the above example, since the line frequency is 200 kHz, it is necessary to perform an operation of 1 cycle as shown in FIG. 17 within a time period of 5 μsec. For example, the time periods Ta, Tb, Tc and Td are set to 2 μsec, 2 μsec, 0.5 μsec and 0.5 μsec, respectively.

In the case where voltage modulation is performed within a single frame time period, in the above example, the single frame time period of the TDI camera is 2.5 msec. Therefore, in a time period of 2.5 msec, an operation of 1 cycle as shown in FIG. 17 is performed. For example, the time periods Ta, Tb, Tc and Td are set to 1 msec, 1 msec, 0.25 msec and 0.25 msec, respectively. In this case, although an operation of 1 cycle as shown in FIG. 17 is performed in the single frame time period, an operation of two or more cycles as shown in FIG. 17 may be performed in the single frame time period.

It should be noted that the aperture 64b for blanking as shown in FIG. 16 is cylindrical, and includes an aperture located on a downstream side. For example, the aperture of the aperture 64b has a diameter of 3 mm, and an end portion of the aperture 64b has a diameter of 6 mm or more. If an electron beam is radiated onto the end portion for a long time, an insulating contamination such as carbon may be generated at the radiated portion. It is therefore preferable that blanking be performed to prevent an influence of the contamination.

Furthermore, if the energy of the electron beam is changed by the voltage modulation, there is a case where the magnification or image distortion of an image formed by the electron image projection system is changed. That is, there is a case where the magnification or image distortion of an electronic image detected by the image detecting unit is changed. In such a case, in the fifth embodiment, with respect to the magnification and the image distortion, adjustment is performed by the following method.

First of all, the conditions of elements of the electron beam radiation system 64, the electron image projection system 65 and the beam separation unit 68 as shown in FIG. 16 are determined in advance to make the magnification and the image distortion constant. Then, in the voltage transition time period, conditions for causing the magnification and image distortion before the voltage transition time period to be the same as those after the voltage transition time period are changed (adjusted). For example, in the example as shown in FIG. 17, in order that the magnification and image distortion in a time period (time period Ta) in which voltage V1 is applied be same as those in a time period (time period Tb) in which voltage V2 is applied, conditions for causing the magnifications and image distortions in the voltage transition time periods (time periods Tc and Td) to be the same are changed (adjusted). The device according to the fifth embodiment comprises an adjusting unit 72 which adjusts at lease one of the magnification and image distortion of an electronic image detected by the image detecting unit. By controlling the electron image projection system 65, etc., by the adjustment unit 72, the conditions for causing the magnifications and image distortions in the voltage transition time periods to be the same are adjusted.

In such a manner, in the fifth embodiment, the magnification and the image distortion before the voltage transition time period can be caused to be the same as those after the voltage transition time period by adjusting at least one of the magnification and image distortion of an electronic image in the voltage transition time period. Also, since in the voltage transition time period, the electron beam is in a blanking state, adjustment can be performed without having an adverse effect on an image acquired by the image detecting unit.

In the above example, the magnification and the image distortion are adjusted within the voltage transition time period. However, in addition to such adjustment, the size of an electron beam to be radiated onto the object by the electron beam radiation system may also be adjusted within the voltage transition time period. To be more specific, the size of the electron beam to be radiated onto the object is adjusted such that the size of the electron beam before the voltage transition time period is equal to that after the voltage transition time period,

### Sixth Embodiment

The sixth embodiment will be explained. It should be noted that basic matters of the sixth embodiment are the same as those of the first embodiment. Thus, the matters explained with respect to the first embodiment will not be re-explained with respect to the sixth embodiment.

In the case where the power supply voltage is switched using a plurality of power supplies, i.e., voltage modulation is performed using a plurality of power supplies, there is a case where a voltage oscillation occurs at the time of switching the voltage. It thus may adversely affect the switching of the voltage at a high speed. In view of this point, in the sixth embodiment, voltage modulation is performed using a single power supply. This will be explained as follows

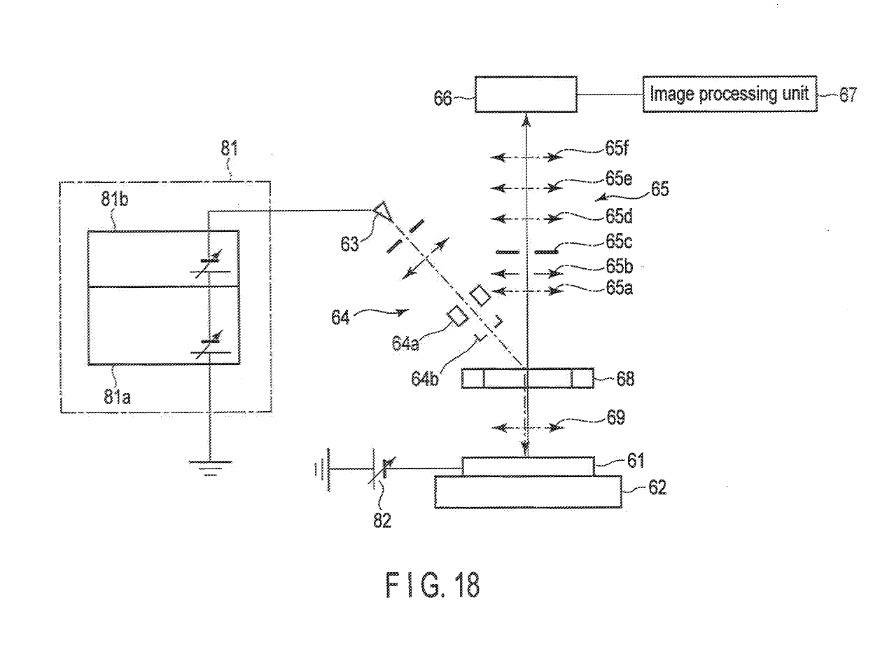

FIG. 18 is a view schematically showing a projection electron microscopy type image acquisition apparatus according to the sixth embodiment. It should be noted that a basic structure of the image acquisition is the same as that of the image acquisition apparatus according to the fifth embodiment, which is provided as shown in FIG. 16. Therefore, structural elements identical to those in FIG. 16 will be denoted by the same reference numerals as in FIG. 16, and their detailed explanations will be omitted.

In the sixth embodiment, a power supply 81 which generates a voltage to be applied to the electron beam source 63 (i.e., a power supply which generates a voltage to be modulated by the voltage modulation unit) comprises a basic voltage generation unit 81a which generates a basic voltage and a superimpose voltage generation unit 81b which generates a superimpose voltage to be superimposed on the basic voltage. Then, by modulating the superimpose voltage, the voltage to be applied to the electron beam source 63 is modulated.

The basic voltage generation unit 81a generates a basic voltage (e.g., a steady voltage), and can generate a voltage whose value falls within the range of, e.g., 0 to −5 kV. The superimpose voltage generation unit 81b can generate a voltage whose value falls within the range of, e.g., 0 to −0.7 kV. In such a manner, the superimpose voltage generation unit 81b can set the voltage within a narrower range than the basic voltage generation unit 81a. Thus, the superimpose voltage generation unit 81b can switch the voltage at a high speed. By switching the voltage of the superimpose voltage generation unit 81b, the power supply voltage can be modulated at a high speed.

A power supply 82 for the object to be measured is connected to the object 61, and a desired voltage is applied to the object 61. The energy of an electron beam is determined in accordance with the difference between the voltage applied from the power supply 82 to the object 61 and the voltage applied from the power supply 81 to the electron beam source 63.

As described above, in the sixth embodiment, the basic voltage generation unit 81a and the superimpose voltage generation unit 81b are provided in a single power supply, i.e. the power supply 81. It is therefore possible to prevent generation of a voltage oscillation at the time of switching the power supply voltage. Furthermore, the superimpose voltage generation unit 81b can set the voltage within a narrower range than the basic voltage generation unit 81a, and thus switch the voltage at a high speed. Therefore, in the sixth embodiment, it is possible to prevent generation of a voltage oscillation, and in addition properly switch the voltage at a high speed.

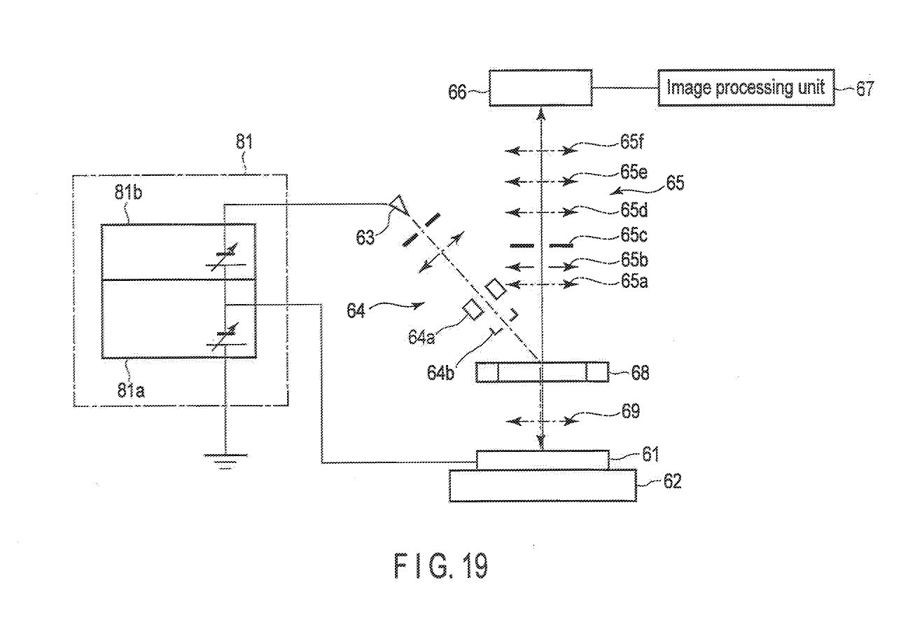

FIG. 19 is a view schematically showing a structure of an projection electron microscopy type image acquisition apparatus according to a modification of the sixth embodiment. It should be noted that a basic structure of the image acquisition apparatus according to the modification is the same as that of the image acquisition apparatus as shown in FIG. 18. Therefore, with respect to the image acquisition apparatus according to the modification, structural elements identical to those in FIG. 18 will be denoted by the same reference numerals as in FIG. 18, and their detailed explanations will be omitted.

As to the modification, as shown in FIG. 19, a voltage from the basic voltage generation unit 81a in the power supply 81 is also applied to the object 61. That is, in the modification, the power supply 81 doubles as both the power supply for the electron beam source 63 and the power supply for the object 61. In such a manner, since the power supply is shared, it is possible to improve the accuracy of the difference between the voltage to be applied to the object 61 and that to be applied to the electron beam source 63.

For example, if power supplies are provided for the electron beam source 63 and the object 61, respectively, ordinarily, a voltage accuracy is obtained with an error of approximately 0.1%. For example, if 5 kV is set, an error of approximately 5V is made. It is therefore necessary to perform an operation for making an adjustment with respect to the voltage error between the above power supplies. In the modification, the voltage difference between the voltage to be applied to the object 61 and the voltage to be applied to the electron beam source 63 is determined in accordance with the precision of setting of the superimpose voltage generation unit 81b, and it thus suffices to make an adjustment only to the superimpose voltage generation unit 81b. Furthermore, the range of a voltage to be generated by the superimpose voltage generation unit 81b is small. For example, if the range of the voltage to be generated by the superimpose voltage generation unit 81b falls within the range from 0 to −0.7 kV, and a voltage accuracy is obtained with an error of approximately 0.1%, an error range is approximately 0.7V. Therefore, from such a point of view also it is possible to reduce the error in the voltage difference between the voltage to be applied to the object 61 and the voltage to be applied to the electron beam source 63.

It should be noted that in the above embodiment, the basic voltage generation unit and the superimpose voltage generation unit are provided in the power supply for the electron beam source; however, they may be provided in the power supply for the object to be measured.

Also, in the above embodiment, the TDI-CCD sensor is applied to the image detecting unit; however, an EB-TDI may be applied thereto.

The first to sixth embodiments have such features as explained above; however, they can be variously modified.

With respect to the above embodiments, the secondary electron image and the mirror electron image are explained as examples of electronic images obtained from the object; however, another or other kinds of electronic images may be applied.

Furthermore, the inspection method using the defect inspection apparatus according to the above embodiments may be applied to a die to die inspection or to a die to database inspection.

While certain embodiments have been described, these embodiments have been presented by way of example only, and are not intended to limit the scope of the invention. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An image acquisition apparatus comprising:
an electron beam source configured to generate an electron beam to be radiated onto an object to be measured;
an image detecting unit configured to detect an electronic image of the object based on the electron beam radiated from the electron beam source onto the object; and
a voltage modulating unit configured to modulate at least one of a voltage to be applied to the electron beam source and a voltage to be applied to the object.

2. The image acquisition apparatus of claim 1, wherein a plurality of kinds of electronic images are detected by the image detecting unit by modulating the at least one of the voltage to be applied to the electron beam source and the voltage to be applied to the object by the voltage modulating unit.

3. The image acquisition apparatus of claim 2, further comprising an image composition unit configured to combine the plurality of kinds of electronic images.

4. The image acquisition apparatus of claim 1, further comprising a synchronization controlling unit configured to synchronize voltage modulation timing by the voltage modulating unit and image detection timing by the image detecting unit with each other.

5. The image acquisition apparatus of claim 1, wherein the electronic image includes a mirror electron image.

6. The image acquisition apparatus of claim 1, further comprising a radiation controlling unit configured to exert a control of preventing the electron beam radiated from the electron beam source from being radiated onto the object, in a transition time period of the voltage modulated by the voltage modulating unit.

7. The image acquisition apparatus of claim 6, which is provided as an projection electron microscopy type image acquisition apparatus including an electron beam radiation system and an electron image projection system, and wherein in the transition time period, the radiation controlling unit performs blanking of the electron beam radiated from the electron beam source in the electron beam radiation system.

8. The image acquisition apparatus of claim 1, further comprising an adjusting unit configured to adjust at least one of a magnification and image distortion of the electronic image detected by the image detecting unit in a transition time period of the voltage modulated by the voltage modulating unit.

9. The image acquisition apparatus of claim 1, further comprising a power supply which generates a voltage to be modulated by the voltage modulating unit, and wherein
the power supply includes a basic voltage generation unit configured to generate a basic voltage and a superimpose voltage generation unit configured to generate a superimpose voltage to be superimposed on the basic voltage, and
the superimpose voltage is modulated by the voltage modulating unit.

10. A defect inspection apparatus comprising:
the image acquisition apparatus of claim 1; and
a defect detecting unit configured to detect a defect in the object to be measured, based on an image acquired by the image acquisition apparatus of claim 1.

11. An image acquisition method comprising:
radiating an electron beam generated by an electron beam source onto an object to be measured; and
detecting with an image detecting unit, an electronic image of the object based on the electron beam radiated onto the object,
wherein, at least one of a voltage to be applied to the electron beam source and a voltage to be applied to the object is modulated by a voltage modulating unit when the electron beam is radiated onto the object.

12. The image acquisition method of claim 11, wherein a plurality of kinds of electronic images are detected by the image detecting unit by modulating the at least one of the voltage to be applied to the electron beam source and the voltage to be applied to the object by the voltage modulating unit.

13. The image acquisition method of claim 12 further comprising:
combining the plurality of kinds of electronic images by an image composition unit.

14. The image acquisition method of claim 11, wherein voltage modulation timing by the voltage modulating unit and image detection timing by the image detecting unit are synchronized with each other.

15. The image acquisition method of claim 11, wherein the electronic image includes a mirror electron image.

16. The image acquisition method of claim 11, wherein the electron beam radiated from the electron beam source is prevented from being radiated onto the object by a radiation controlling unit, in a transition time period of the voltage modulated by the voltage modulating unit.

17. The image acquisition method of claim 16, which is executed by an projection electron microscopy type image acquisition apparatus including an electron beam radiation system and an electron image projection system, and wherein in the transition time period, the radiation controlling unit performs blanking of the electron beam radiated from the electron beam source in the electron beam radiation system.

18. The image acquisition method of claim 11, wherein at least one of a magnification and an image distortion of the electronic image detected by the image detecting unit is adjusted in a transition time period of the voltage modulated by the voltage modulating unit.

19. The image acquisition method of claim 11, wherein a power supply which generates a voltage to be modulated by the voltage modulating unit includes a basic voltage generation unit configured to generate a basic voltage and a superimpose voltage generation unit configured to generate a superimpose voltage to be superimposed on the basic voltage, and the superimpose voltage is modulated by the voltage modulating unit.
